(19) United States
(12) Patent Application Publication
(10) Pub. No.: US 2025/0132727 A1
(43) Pub. Date: Apr. 24, 2025

(54) LOW-SPEED OSCILLATOR WITH REDUCED OVERVOLTAGE

(71) Applicant: Sony Semiconductor Solutions Corporation, Kanagawa (JP)

(72) Inventors: Eric Bohannon, San Diego, CA (US); Zhiwei Mao, Rochester, NY (US)

(21) Appl. No.: 18/836,546

(22) PCT Filed: Feb. 14, 2023
(86) PCT No.: PCT/IB2023/051300

§ 371 Date: Aug. 7, 2024

Related U.S. Application Data
(60) Provisional application No. 63/309,778, filed on Feb. 14, 2022.

(51) Int. Cl. H03B 5/24

(52) U.S. Cl. CPC H03B 5/24

(57) ABSTRACT

Oscillator circuits, electronic devices, and methods are disclosed. In one embodiment, an oscillator circuit includes a first inverter, a second inverter, a third inverter, a resistor, an enable transistor with a gate of the enable transistor is configured to receive a first enable signal, a first capacitor, and a second capacitor that forms a capacitor divider with the first capacitor. The capacitor divider limits a first voltage at the first inverter to a voltage range between the supply voltage and the ground.

### CROSS-REFERENCE TO RELATED APPLICATION

This application claims the benefit of, and priority to, U.S. Provisional Application No. 63/309,778, filed on Feb. 14, 2022, the entire contents of which are incorporated herein by reference.

### BACKGROUND OF THE INVENTION

### 1. Field of the Invention

This application relates generally to electronic devices. More specifically, this application relates to electronic devices with a low-speed oscillator with reduced overvoltage.

### 2. Description of Related Art

Input devices, including proximity sensor devices (e.g., touchpads or touch sensor devices), are widely used in a variety of electronic systems. A proximity sensor device may include a sensing region, often demarked by a surface, in which the proximity sensor device determines the presence, location and/or motion of one or more input objects. Proximity sensor devices may be used to provide interfaces for the electronic system. For example, proximity sensor devices may be used as input devices for larger computing systems (e.g., opaque touchpads integrated in, or peripheral to, notebook or desktop computers). Proximity sensor devices are also often used in smaller computing systems (e.g., touch screens integrated in cellular phones). Proximity sensor devices may also be used to detect input objects (e.g., finger, styli, pens, fingerprints, etc.).

Many electronic devices, including input devices, may be expected to operate over a wide range of temperatures and with minimal power. Oscillators are often used to provide clock signals. However, oscillation frequency can be affected by temperature changes or by device breakdown, thereby affecting the clock signals. Accordingly, it may be desirable for the electronic devices to include circuitry that provides a stable oscillation frequency over the wide range of temperatures that minimizes device breakdown, especially device breakdown in transistors that are included in a digital inverter.

### BRIEF SUMMARY OF THE INVENTION

In view of the foregoing, there is a need for a low-speed oscillator that reduces or eliminates device breakdown. The low-speed oscillator of the present disclosure reduces or eliminates overvoltage with respect to inverters in the low-speed oscillator. Consequently, the low-speed oscillator of the present disclosure reduces or eliminates the device breakdown in the inverters because the inverters are subjected to either a reduced overvoltage or no overvoltage.

In one aspect of the present disclosure, there is provided an oscillator circuit. The oscillator circuit including a first inverter that is electrically connected to a supply voltage, a first node, and a second node, a second inverter that is electrically connected to the supply voltage, the second node, and a third node, a third inverter that is electrically connected to the supply voltage, the third node, and a fourth node, a resistor that is electrically connected to the fourth node, an enable transistor that is electrically connected to the supply voltage and a fifth node, wherein a gate of the enable transistor is configured to receive a second enable signal, a first capacitor that is electrically connected to the third node and a sixth node that is electrically connected to the fifth node, and a second capacitor that is electrically connected to the sixth node and a ground. The first capacitor and the second capacitor form a capacitor divider, and the capacitor divider limits a first voltage at the first node to a voltage range between the supply voltage and the ground.

In another aspect of the present disclosure, there is provided an electronic device including an oscillator circuit. The oscillator circuit includes a first inverter that is electrically connected to a supply voltage, a first node, and a second node, a second inverter that is electrically connected to the supply voltage, the second node, and a third node, a third inverter that is electrically connected to the supply voltage, the third node, and a fourth node, a resistor that is electrically connected to the fourth node, an enable transistor that is electrically connected to the supply voltage and a fifth node, wherein a gate of the enable transistor is configured to receive a second enable signal, a first capacitor that is electrically connected to the third node and a sixth node that is electrically connected to the fifth node, and a second capacitor that is electrically connected to the sixth node and a ground. The first capacitor and the second capacitor form a capacitor divider, and the capacitor divider limits a first voltage at the first node to a voltage range between the supply voltage and the ground.

In yet another aspect of the present disclosure, there is provided a method for operating an oscillator circuit. The method includes generating, with a control circuitry, a first enable signal. The method also includes outputting, with the control circuitry, the first enable to control an enable transistor of an oscillator circuit to change from an OPEN state to a CLOSED state or from the CLOSED state to the OPEN state. The oscillator circuit includes the enable transistor, a plurality of inverters, a first capacitor and a second capacitor forming a capacitor divider, and a resistor. A first inverter of the plurality of inverters is electrically connected to a supply voltage, a first node, and a second node. The enable delay switch and the capacitor divider limits a first voltage at the first node to a voltage range between the supply voltage and the ground.

In this manner, the above aspects of the present disclosure provide for improvements in at least the technical field of imaging, as well as the related technical fields of signal processing, image processing, and the like.

This disclosure can be embodied in various forms, including hardware or circuits controlled by computer-implemented methods, computer program products, computer systems and networks, user interfaces, and application programming interfaces; as well as hardware-implemented methods, signal processing circuits, image sensor circuits, application specific integrated circuits, field programmable gate arrays, and the like. The foregoing summary is intended solely to give a general idea of various aspects of the present disclosure, and does not limit the scope of the disclosure in any way.

### DESCRIPTION OF THE DRAWINGS

These and other more detailed and specific features of various embodiments are more fully disclosed in the following description, reference being had to the accompanying drawings, in which:

FIG. 1 is a block diagram illustrating an electronic device including an example of a complementary metal-oxide-semiconductor (CMOS) oscillator that has a reduced overvoltage, in accordance with various aspects of the present disclosure;

FIG. 2 is a circuit diagram illustrating an example of a low-speed oscillator;

FIG. 3 is a chart illustrating an overvoltage of the low-speed oscillator of FIG. 2;

FIG. 4 is a circuit diagram illustrating a second example of a low-speed oscillator;

FIG. 5 is a circuit diagram illustrating a third example of a low-speed oscillator 500, in accordance with various aspects of the present disclosure;

FIG. 6 is a plot illustrating oscillation frequencies versus adjust code at different corner conditions of the CMOS oscillator 500 of FIG. 5, in accordance with various aspects of the present disclosure; and

FIG. 7 is a flowchart illustrating a process for operating the low-speed oscillator of FIG. 5, in accordance with various aspects of the present disclosure.

### DETAILED DESCRIPTION

In the following description, numerous details are set forth, such as flowcharts, data tables, and system configurations. It will be readily apparent to one skilled in the art that these specific details are merely exemplary and not intended to limit the scope of this application.

Moreover, while the present disclosure focuses mainly on examples in which the processing circuits are used in image sensors, it will be understood that this is merely one example of an implementation. It will further be understood that the disclosed systems and methods can be used in any device in which there is a need to reduce noise in a signal processing or other analog circuit; for example, an audio signal processing circuit, industrial measurement and systems, and the like. Furthermore, the image sensor implementations described below may be incorporated into an electronic apparatus, including but not limited to a smartphone, a tablet computer, a laptop computer, and the like.

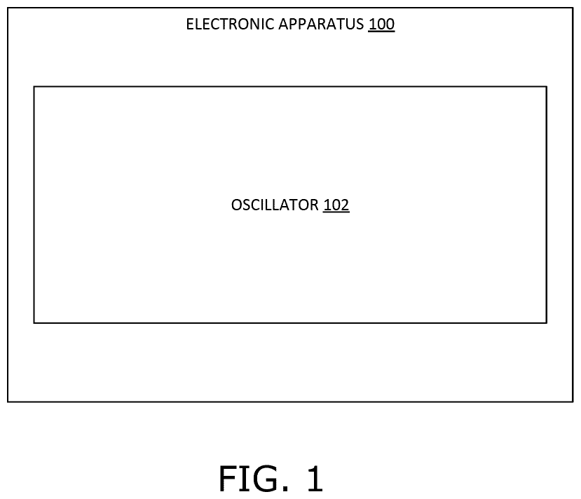

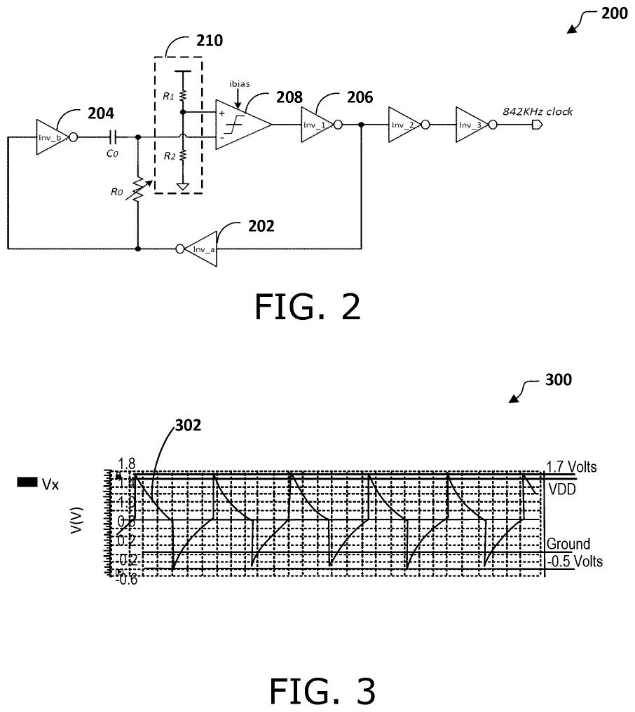

FIG. 1 is a block diagram illustrating an electronic device 100 including an example of a complementary metal-oxide-semiconductor (CMOS) oscillator 102 that has a reduced overvoltage, in accordance with various aspects of the present disclosure. In the example of FIG. 1, the electronic device 100 may an imaging device. However, the electronic device 100 is not limited to an imaging device, but may be any device that uses a clock signal, for example, a smartphone, a table computer, a laptop computer, or other device that uses a clock signal. In some examples, the electronic device 100 may be an application-specific integrated circuit (ASIC). In other examples, the electronic device 100 may be a phase-locked loop (PLL), a radio frequency (RF) transceiver, a display, an ultrasonic sensor, a capacitive sensor, or any other electronic device that generates transmit or drive signals. The CMOS oscillator 102 generates a periodic signal (e.g., a sine wave or a square wave) and is described in more detail below in FIGS. 2-7.

Low-Speed Oscillator with Resistor Divider and Comparator

FIG. 2 is a circuit diagram illustrating an example of a low-speed oscillator 200. The term “low-speed” herein is considered below 100 megahertz (100 MHz).

The low-speed oscillator 200 relies on three key inverters 202, 204, and 206 (Inv_a, Inv_b, and Inv_1, respectively), an analog comparator 208, and a resistor divider 210. The resistor divider 210 creates a reference voltage for the comparator 208, which consumes DC power and necessitates large resistors to reduce the power. The comparator 208 undesirably consumes DC power via its bias current (labeled as i_{bias} in FIG. 2). This bias current is typically created from a bias circuit, which also undesirably consumes circuit area and DC power.

However, the low-speed oscillator 200 has a potential silicon problem and the root-cause of this problem is coupling capacitance from the inverting terminal of the comparator 208 to an internal node of the comparator 208. Specifically, the coupling capacitance from the gate of the inverting terminal input pair transistor to that transistors drain. This coupling capacitance, when large enough in certain common comparator architectures, causes the final output (a divide-by-2 version of the internal clock frequency for 50% duty cycle) of the oscillator 200 to not produce a valid clock signal. This problem motivates using a different low-speed oscillator architecture. The oscillator 200 is also difficult to implement on smaller geometry CMOS nodes (e.g., 22 nanometer (nm) and smaller) where supply voltages are much less than 1 volt (V) (e.g., 800 millivolts (mV)).

FIG. 3 is a chart illustrating an overvoltage 300 of the low-speed oscillator 200 of FIG. 2. In the example of FIG. 3, the supply voltage (VDD) is 1.5 volts and the ground is 0 volts. As illustrated in FIG. 3, the voltage line 302 changes between 1.7 volts and −0.5 volts even though the supply voltage VDD is 1.2 volts and the ground is 0 volts. The difference between 1.7 and 12 and the difference between 0 and −0.5 is the overvoltage 300 of the low-speed oscillator 200 of FIG. 2.

Low-Speed Oscillator with CMOS Inverters

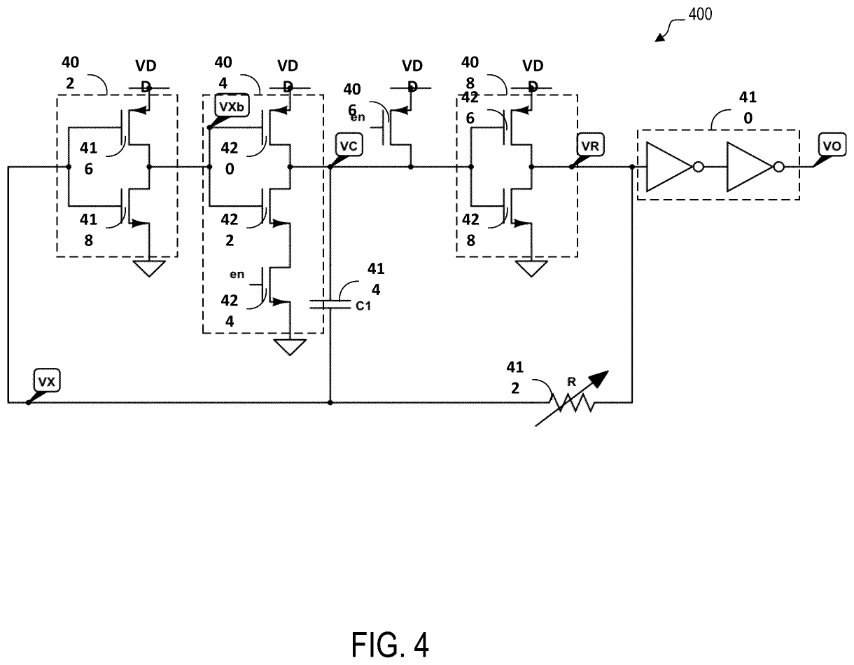

FIG. 4 is a circuit diagram illustrating a second example of a low-speed oscillator 400. The architecture of the low-speed oscillator 400 includes a first inverter 402, a second inverter 404, a first enable transistor 406, a third inverter 408, a string of inverters 410, a resistor 412, and a capacitor 414.

The first inverter 402 is a CMOS inverter including a P-channel metal-oxide-semiconductor (PMOS) transistor 416 and a N-channel metal-oxide-semiconductor (NMOS) transistor 418, where the gates of the transistors 416 and 418 are tied together and connected to a first node that has a voltage VX. The drain of the PMOS transistor 416 is electrically connected to the source of the NMOS transistor 418, and the electrical connection between the drain of the PMOS transistor 416 and the source of the NMOS transistor 418 is electrically connected to a second node that has a voltage VXb.

The second inverter 404 is a CMOS inverter including a PMOS transistor 420 and a NMOS transistor 422 in addition to a second enable transistor 424 (e.g., an NMOS transistor). The gates of the PMOS transistor 420 and the NMOS transistor 422 are tied together and connected to the second node. The drain of the PMOS transistor 420 is electrically connected to the source of the NMOS transistor 422, and the electrical connection between the drain of the PMOS transistor 420 and the source of the NMOS transistor 422 is electrically connected to a third node that has a voltage VC.

A gate of the first enable transistor 406 (e.g., a PMOS transistor) is electrically connected to receive an enable control signal. A drain of the first enable transistor 406 is electrically connected to the third node that has the voltage VC. A source of the first enable transistor 406 is electrically connected to the supply voltage VDD.

The third inverter 408 is a CMOS inverter including a PMOS transistor 426 and an NMOS transistor 428, where the gates of the PMOS transistor 426 and the NMOS transistor 428 are tied together and connected to the third node that has the voltage VC. The drain of the PMOS transistor 426 is electrically connected to the source of the NMOS transistor 428, and the electrical connection between the drain of the PMOS transistor 426 and the source of the NMOS transistor 428 is electrically connected to a fourth node that has a voltage VR.

The fourth node is electrically connected to the string of inverters 410. The string of inverters 410 is connected between an output node that has an output voltage VO and the fourth node.

A first end of the resistor 412 (e.g., an adjustable resistor) is electrically connected to the fourth node. A second end of the resistor 412 is electrically connected to a fifth node that is also electrically connected to the first node.

A first end of the capacitor 414 is electrically connected to the third node. A second end of the capacitor 414 is electrically connected to the fifth node.

When the low-speed oscillator 400 is disabled, the voltage VX is at ground, the voltage VXb is at VDD, the voltage VC is at VDD, and the voltage VR is at ground. In other words, when the low-speed oscillator 400 is disabled, the voltages VXb and VC are both at VDD.

When the low-speed oscillator 400 is enabled, the voltage VXb stays at VDD and the low-speed oscillator 400 immediately pulls the voltage VC to ground. When the capacitor 414 (C1) is large relative to the parasitic capacitance on the transistors 406 and 416-428, then the voltage VX (which was at ground when the low-speed oscillator 400 was disabled) will follow the movement on the capacitor 414 and move to −VDD (because the charge across the capacitor 414 cannot change instantaneously). However, the voltage VR (which is an inverted version of VC) will be at VDD. Hence the voltage VR, which is at VDD, will charge the voltage VX, which is at −VDD to the voltage needed to trip the first inverter 402.

Assuming the trip point of the first inverter 402 is VDD/2, then the first inverter 402 will trip when the voltage VX reaches VDD/2. When the voltage VX reaches VDD/2, the voltage VXb will go to ground, the voltage VC will go to VDD, and the voltage VR will go to ground. When the voltage VC goes to VDD (and noting that the charge across C1 cannot change instantaneously), the voltage VX, which was at VDD/2, will now go to 3VDD/2. The voltage VX will now discharge to its trip point, VDD/2, through the resistor 412 and the capacitor 414 via the voltage VR at the fourth node.

After the voltage VX reaches its trip point, the first inverter 402 will swing to −3VDD/2 due to the voltage VC going to ground. This process will repeat itself such that the low-speed oscillator 400 oscillates.

The challenge with this architecture of the low-speed oscillator 400 is that the voltage on VX goes above VDD and below ground. Therefore, in order to prevent transistor oxide breakdown, high-voltage transistors (with thick oxides) are needed in the first inverter 402. However, thick oxides are difficult to implement as thick oxides may add mask costs (e.g., paying for transistors that are only in this circuit). Thick oxide transistors (2.5 V transistors or greater than 2.5 V transistors, for example) are also difficult to use in circuits with a VDD meant for thin-oxide transistors (0.8 V transistors or less than 0.8 V transistors, for example) because the threshold voltage of the thick oxide transistors approaches the supply voltage of the thin-oxide transistors. This makes it difficult to design the oscillator in FIG. 4 with a thick-oxide inverter (402) because the inverters trip point will not be well defined. Also, the resistance of the switches will be increased due to the threshold voltage of the thick-oxide transistors being comparable to VDD of the inverter. This will effectively reduce the frequency of the oscillator.

Additionally, thick oxides causes a problem when scaling down, for example, at twenty-two nanometers (nm). The properties of thick oxide transistors do not simply scale to 800 millivolts supply voltage, for example. The thick oxide inverters have threshold voltages of 500 to 630 millivolts, where the inverter trips from high to low or low to high. Consequently, the thick oxide device is not well controlled over VDD or temperature so an oscillator with a thick oxide device becomes difficult to have accuracy on the oscillation frequency.

Low-Speed Oscillator with CMOS Inverters, Capacitor Divider, and Enable Delay Switch

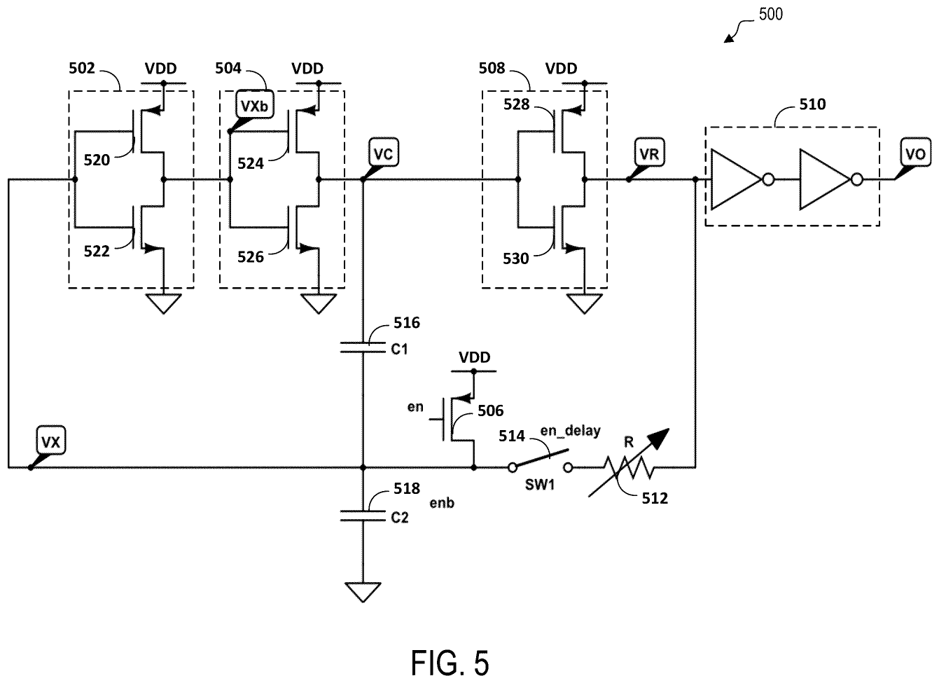

FIG. 5 is a circuit diagram illustrating a third example of a low-speed oscillator 500, in accordance with various aspects of the present disclosure. The low-speed oscillator 500 is one example of the oscillator 102 of FIG. 1. The architecture of the low-speed oscillator 500 includes a first inverter 502, a second inverter 504, an enable transistor 506, a third inverter 508, a string of inverters 510, a resistor 512, a first delay switch 514, a first capacitor 516, a second capacitor 518.

The first inverter 502 is a CMOS inverter including a PMOS transistor 520 and an NMOS transistor 522, where the gates of the PMOS transistor 520 and the NMOS transistor 522 are tied together and connected to a first node that has a voltage VX. The drain of the PMOS transistor 520 is electrically connected to the source of the NMOS transistor 522, and the electrical connection between the drain of the PMOS transistor 520 and the source of the NMOS transistor 522 is electrically connected to a second node that has a voltage VXb.

The second inverter 504 is a CMOS inverter including a PMOS transistor 522 and an NMOS transistor 524. The gates of the PMOS transistor 522 and the NMOS transistor 524 are tied together and connected to the second node. The drain of the PMOS transistor 522 is electrically connected to the source of the NMOS transistor 524, and the electrical connection between the drain of the PMOS transistor 522 and the source of the NMOS transistor 524 is electrically connected to a third node that has a voltage VC.

The third inverter 508 is a CMOS inverter including a PMOS transistor 528 and an NMOS transistor 530, where the gates of the PMOS transistor 528 and the NMOS transistor 530 are tied together and connected to the third node that has the voltage VC. The drain of the PMOS transistor 528 is electrically connected to the source of the NMOS transistor 530, and the electrical connection between the drain of the PMOS transistor 528 and the source of the NMOS transistor 530 is electrically connected to a fourth node that has a voltage VR.

The fourth node is electrically connected to the string of inverters 510. The string of inverters 510 is connected between an output node that has an output voltage VO and the fourth node.

A first end of the resistor 512 (e.g., an adjustable resistor) is electrically connected to the fourth node. A second end of the resistor 512 is electrically connected to a first end of the enable delay switch 514. A second end of the enable delay switch is electrically connected to a fifth node. The enable delay switch 514 is called “enable delay” because a delay exists between the enable signal with respect to the enable transistor 506 and the enable signal with respect to the enable delay switch 514. In other words, the enable delay switch 514 will always open and close on a slight delay with respect to the enable transistor 506. This slight delay prevents an overvoltage condition in the low-speed oscillator 500 at time zero.

In some embodiments, as illustrated in FIG. 5, the enable delay switch 514 is included in the low-speed oscillator 500 to reduce or eliminate one overvoltage pulse when the low-speed oscillator 500 is first enabled and no further overvoltage after that pulse. In other embodiments, where one overvoltage pulse is considered a tolerable overvoltage because it is significantly reduced in the low-speed oscillator 500 compared to the low-speed oscillator 200 and the low-speed oscillator 400, then the enable delay switch 514 may be excluded from the low-speed oscillator 500. In these other embodiments, there would be one overvoltage pulse when the low-speed oscillator 500 is first enabled and no further overvoltage after that pulse.

A gate of the first enable transistor 506 (e.g., a PMOS transistor) is electrically connected to receive an enable control signal. A drain of the first enable transistor 506 is electrically connected to the fifth node. A source of the first enable transistor 506 is electrically connected to the supply voltage VDD.

A first end of the first capacitor 514 is electrically connected to the third node. A second end of the first capacitor 514 is electrically connected to the fifth node. A first end of the second capacitor 516 is electrically connected to the fifth node. A second end of the second capacitor 516 is electrically connected to a ground.

When the low-speed oscillator 500 is disabled, the voltage VX is at VDD, the voltage VXb is at ground, the voltage VC is at VDD, the voltage VR is at ground, and the enable delay switch 514 (SW1) is in an OPEN state. When the low-speed oscillator 500 is enabled, the enable transistor 506 closes slightly before the enable delay switch 514 (SW1). In some examples, the delay associated with the enable delay switch 514 may be implemented with simple inverter delays. In other examples, the delay associated with the enable delay switch 514 may be implemented with a delay by control circuitry.

After the low-speed oscillator 500 is enabled, the node voltages are the same as in the disabled state of the low-speed oscillator 500. Given that the voltage VR is at ground, this causes the voltage VX to discharge from VDD to the trip threshold of the first inverter 502.

Assuming the trip point of the first inverter 502 is at VDD/2, then once the first inverter 502 trips, the voltage VXb is at VDD, the voltage VC is at ground, and the volage VR is at VDD. Assuming the first capacitor 516 is equal to the second capacitor 518 and that the first capacitor 516 is large relative to the parasitic capacitance of the transistors 506 and 520-530, then the voltage VX will decrease from VDD/2 to ground because of the capacitor divider created by the first capacitor 516 and the second capacitor 518.

The process described above will then repeat but in the opposite direction. The voltage VX will charge up from ground to the trip point of the first inverter 502 (e.g., at VDD/2) via the voltage VR. When the first inverter 502 trips, the voltage VXb is at ground, the voltage VC is at VDD, and the voltage VR is at ground. The voltage VX will increase from VDD/2 to VDD because of the capacitor divider created by the first capacitor 516 and the second capacitor 518. This process will repeat itself such that a voltage at the first node having the voltage VX is limited to oscillating between ground and VDD.

As described, the voltage VX does not go above VDD or below ground. Thus, the overvoltage concern is eliminated and the first inverter 502 electrically connected to the first node may be implemented with transistors having an oxide thickness that matches the target supply voltage. The elimination of the overvoltage concern simplifies the design because it is more practical to design the first inverter 502 with a trip point of VDD/2 when using transistors with oxide thicknesses that match the supply voltage. Additionally, the elimination of the overvoltage concern also reduces manufacturing costs because transistors 506 and 520-530 (and in some examples, the enable delay switch 514) may have the same oxide thickness. Note that the elimination of the overvoltage was accomplished by adding the second capacitor 518 to create a capacitor divider with the first capacitor 516, changing the location of the enable transistor 506 relative to a location of the enable transistor 406 in FIG. 4, and adding the enable delay switch 514. Also, note that an expression for the oscillator period, T, can be set forth as Expression (1) below:

$$T = R \cdot ( {C}_{1} + {C}_{2} ) \cdot ln ( \frac{α + \frac{{C}_{1}}{{C}_{1} + {C}_{2}}}{α} \cdot \frac{\frac{{C}_{1}}{{C}_{1} + {C}_{2}} + 1 - α}{1 - α} ) \qquad ( 1 )$$

Where the trip point of the first inverter 502 is defined as, V_{TRIP}=α·V_{DD}. Note that for α=0.5 and a capacitance of the first capacitor 516 (C1) is equal to a capacitance of the second capacitor 518 (C2), then the expression for the oscillator period, T, can be set forth as Expression (2) below:

$$T = 4 \cdot R \cdot {C}_{1} \cdot ln ( 4 ) \qquad ( 2 )$$

The oscillator period, T, may be adjusted by changing the capacitance of the first capacitor 516 to be different from the capacitance of the second capacitor 518. Also note that, assuming the capacitance of the second capacitor 518 is targeted as being equal to the capacitance of the first capacitor 516, a parasitic capacitance at the first node with the voltage VX will prevent the second capacitor 518 from effectively being larger than the first capacitor 516, thus reducing or eliminating any small overvoltage concerns.

In some examples, the oscillator frequency may also be calibrated via a DAC associated with the resistor 512. Additionally, in some examples, in a 22 nm CMOS technology, the minimum supply voltage may be 720 mV.

The low-speed oscillator 500 from a system perspective may be used in low power modes to clock the digital portions of a processing chip that remains active in a low power mode, where the chip may remain in some type of mode to wake up and react to any new information.

The major change relative to the low-speed comparator 200 is that the low-speed comparators 400 and 500 do not have a analog comparator. Additionally, the introduction of the second capacitor 518 creates a capacitor divider between the voltage VC and the voltage VX such that the voltage VX now never goes above VDD and never goes below ground.

The capacitor divider also allows the first inverter 502 to be a thin oxide device or the same inverter as all the other inverters in the low-speed oscillator 500. These other inverters being used with the 720 mV supply voltage.

The introduction of the second capacitor 518 keeps the voltage VX voltage within the rails, so the first inverter 502 will be relatively accurate in terms of its trip point over process, over temperature, and over a power supply voltage. The introduction of the enable delay switch 514 also prevents current consumption by the resistor 512 when the voltage VX is high and the voltage VR is low.

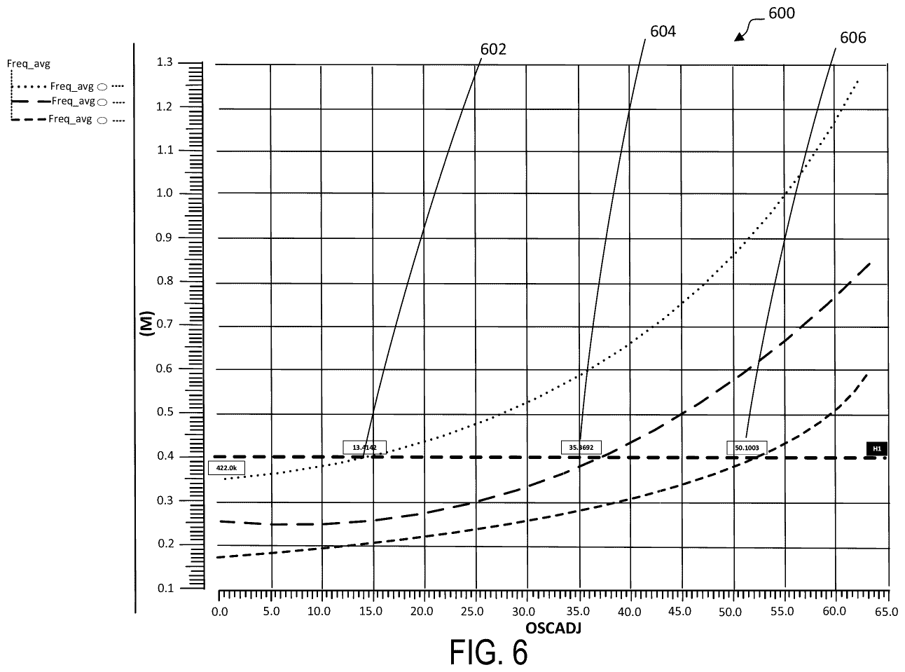

FIG. 6 is a plot 600 illustrating oscillation frequencies versus adjust code at different corner conditions of the CMOS oscillator 500 of FIG. 5, in accordance with various aspects of the present disclosure. As shown in FIG. 6, the target oscillator frequency (e.g., 422 kHz) may be hit even as the manufacturing process changes. The X-axis is a digital adjust code that corresponds to a selectable resistor (e.g., the resistor 512). As the process varies (resistors increase/decrease and/or capacitors increase/decrease) the adjust code may be changed to make sure the target frequency is hit. The digital adjust code accounts for the impact of process variations on analog circuits.

As illustrated in FIG. 6, with respect to the horizontal dash line 602 at 422 kilohertz and the curve 604, a digital adjust code of 13 or 14 hit the target frequency. As illustrated in FIG. 6, with respect to the horizontal dash line 602 at 422 kilohertz and the curve 606, a digital adjust code about 34 to 36 hit the target frequency. Lastly, as illustrated in FIG. 6, with respect to the horizontal dash line 602 at 422 kilohertz and the curve 608, a digital adjust code of 50 to 51 hit the target frequency.

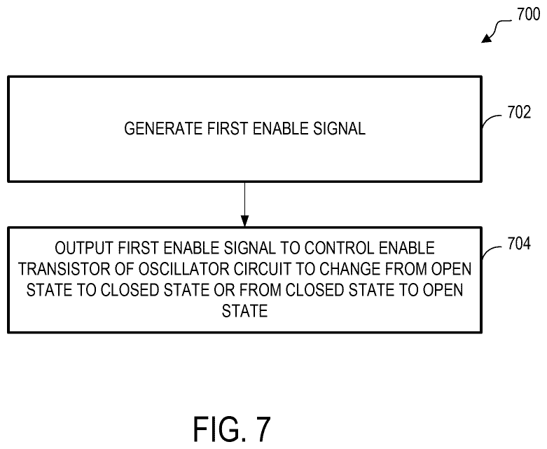

FIG. 7 is a flowchart illustrating a process 700 for operating the low-speed oscillator 500 of FIG. 5, in accordance with various aspects of the present disclosure. The process 700 includes a control circuitry generating a first enable signal (at block 702). In some examples, the first enable signal is generated by a controller including an electronic processor and a memory. In other examples, the first enable signal is generated by other control circuitry. The process 700 also includes the control circuitry outputting the first enable signal to control an enable transistor of an oscillator circuit to change from an OPEN state to a CLOSED state or from the CLOSED state to the OPEN state (at block 704).

In some examples, the process 700 may also include generating a second enable signal and outputting the second enable signal to control an enable delay switch of the oscillator circuit to change from an OPEN state to a CLOSED state or from the CLOSED state to the OPEN state. In some examples, the second enable signal is generated by the controller including the electronic processor and the memory. In other examples, the second enable signal is generated by other control circuitry.

In the process 700, the second enable signal may be based on and delayed relative to the first enable signal. In the process 700, the oscillator circuit includes the enable transistor, the enable delay switch, a plurality of inverters, a first capacitor and a second capacitor forming a capacitor divider, and a resistor. Further, in the process 700, a first inverter of the plurality of inverters is electrically connected to a supply voltage, a first node, and a second node, and the enable delay switch and the capacitor divider limits a first voltage at the first node to a voltage range between the supply voltage and the ground.

Additionally, in some examples, generating the second enable signal to control the enable delay switch of the oscillator circuit to change from the OPEN state to the CLOSED state or from the CLOSED state to the OPEN state may further include generating, with an inverter delay string, the second enable signal by delaying the first enable signal, the inverter delay string electrically connected to a gate of the enable delay switch.

The following are enumerated examples of oscillator circuits, electronic devices, and methods of the present disclosure. Example 1: an oscillator circuit comprising: a first inverter that is electrically connected to a supply voltage, a first node, and a second node; a second inverter that is electrically connected to the supply voltage, the second node, and a third node; a third inverter that is electrically connected to the supply voltage, the third node, and a fourth node; a resistor that is electrically connected to the fourth node; an enable transistor that is electrically connected to the supply voltage and a fifth node, wherein a gate of the enable transistor is configured to receive a second enable signal; a first capacitor that is electrically connected to the third node and a sixth node that is electrically connected to the fifth node; and a second capacitor that is electrically connected to the sixth node and a ground, wherein the first capacitor and the second capacitor form a capacitor divider, and wherein the capacitor divider limits a first voltage at the first node to a voltage range between the supply voltage and the ground.

Example 2: the oscillator circuit of Example 1, further comprising: an enable delay switch that is electrically connected to the resistor and the fifth node, wherein a gate of the enable delay switch is configured to receive a first enable signal; and an inverter delay string electrically connected to the gate of the enable delay switch, the inverter delay string configured to generate the second enable signal by delaying the first enable signal, wherein the enable delay switch and the capacitor divider limits the first voltage at the first node to the voltage range between the supply voltage and the ground.

Example 3: the oscillator circuit of Examples 1 or 2, further comprising: an inverter string electrically connected to the fourth node.

Example 4: the oscillator circuit of Examples 1 through 3, wherein the first capacitor has a first capacitance, wherein the second capacitor has a second capacitance that is equal to the first capacitance.

Example 5: the oscillator circuit of Examples 1 through 4, wherein the first inverter, the second inverter, and the third inverter are each a complementary metal-oxide-semiconductor (CMOS) inverter.

Example 6: the oscillator circuit of Examples 1 through 5, wherein the enable transistor is a P-channel metal-oxide-semiconductor (PMOS) transistor.

Example 7: the oscillator circuit of Examples 1 through 6, wherein, when the enable transistor is in an OPEN state, the first voltage at the first node is equal to the supply voltage, a second voltage at the second node is equal to the ground, a third voltage at the third node is equal to the supply voltage, and wherein a fourth voltage at the fourth node is equal to the ground.

Example 8: the oscillator circuit of Example 7, wherein, when the enable transistor changes from the OPEN state to a CLOSED state, the first voltage at the first node changes from the supply voltage to be equal to the ground, the second voltage at the second node changes from the ground to be equal to the supply voltage, the third voltage at the third node changes from the supply voltage to be equal to the ground, and wherein the fourth voltage at the fourth node changes from the ground to be equal to the supply voltage.

Example 9: the oscillator circuit of Examples 1 through 8, wherein the first inverter, the second inverter, and the third inverter each include a plurality of transistors, and wherein all of the transistors in the first inverter, the second inverter, and the third inverter have the same oxide thickness.

Example 10: an electronic device comprising: an oscillator circuit including a first inverter that is electrically connected to a supply voltage, a first node, and a second node; a second inverter that is electrically connected to the supply voltage, the second node, and a third node; a third inverter that is electrically connected to the supply voltage, the third node, and a fourth node; a resistor that is electrically connected to the fourth node; an enable transistor that is electrically connected to the supply voltage and a fifth node, wherein a gate of the enable transistor is configured to receive a second enable signal; a first capacitor that is electrically connected to the third node and a sixth node that is electrically connected to the fifth node; and a second capacitor that is electrically connected to the sixth node and a ground, wherein the first capacitor and the second capacitor form a capacitor divider, and wherein the capacitor divider limits a first voltage at the first node to a voltage range between the supply voltage and the ground.

Example 11: the electronic device of Example 10, further comprising: an enable delay switch that is electrically connected to the resistor and the fifth node, wherein a gate of the enable delay switch is configured to receive a first enable signal; and an inverter delay string electrically connected to the gate of the enable delay switch, the inverter delay string configured to generate the second enable signal by delaying the first enable signal, wherein the enable delay switch and the capacitor divider limits the first voltage at the first node to the voltage range between the supply voltage and the ground.

Example 12: the electronic device of Examples 10 or 11, further comprising: an inverter string electrically connected to the fourth node.

Example 13: the electronic device of Examples 10 through 12, wherein the first capacitor has a first capacitance, wherein the second capacitor has a second capacitance that is equal to the first capacitance.

Example 14: the electronic device of Examples 10 through 13, wherein the first inverter, the second inverter, and the third inverter are each a complementary metal-oxide-semiconductor (CMOS) inverter.

Example 15: the electronic device of Examples 10 through 14, wherein the enable transistor is a P-channel metal-oxide-semiconductor (PMOS) transistor.

Example 16: the electronic device of Examples 10 through 15, wherein, when the enable transistor is in an OPEN state, the first voltage at the first node is equal to the supply voltage, a second voltage at the second node is equal to the ground, a third voltage at the third node is equal to the supply voltage, and wherein a fourth voltage at the fourth node is equal to the ground.

Example 17: the electronic device of Example 16, wherein, when the enable transistor changes from the OPEN state to a CLOSED state, the first voltage at the first node changes from the supply voltage to be equal to the ground, the second voltage at the second node changes from the ground to be equal to the supply voltage, the third voltage at the third node changes from the supply voltage to be equal to the ground, and wherein the fourth voltage at the fourth node changes from the ground to be equal to the supply voltage.

Example 18: the electronic device of Examples 10 through 17, wherein the first inverter, the second inverter, and the third inverter each include a plurality of transistors, and wherein all of the transistors in the first inverter, the second inverter, and the third inverter have the same oxide thickness.

Example 19: a method for operating an oscillator circuit, the method comprising: generating, with a control circuitry, a first enable signal; and outputting, with the control circuitry, the first enable to control an enable transistor of an oscillator circuit to change from an OPEN state to a CLOSED state or from the CLOSED state to the OPEN state, wherein the oscillator circuit includes the enable transistor, a plurality of inverters, a first capacitor and a second capacitor forming a capacitor divider, and a resistor, wherein a first inverter of the plurality of inverters is electrically connected to a supply voltage, a first node, and a second node, and wherein the enable delay switch and the capacitor divider limits a first voltage at the first node to a voltage range between the supply voltage and the ground.

Example 20: the method of example 19, further comprising: generating a second enable signal; and outputting the second enable signal to control an enable delay switch of the oscillator circuit to change from an OPEN state to a CLOSED state or from the CLOSED state to the OPEN state, wherein the second enable signal is based on and delayed relative to the first enable signal, wherein the oscillator circuit further includes the enable delay switch, and wherein the enable delay switch and the capacitor divider limits the first voltage at the first node to the voltage range between the supply voltage and the ground.

### CONCLUSION

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain embodiments, and should in no way be construed so as to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their broadest reasonable constructions and their ordinary meanings as understood by those knowledgeable in the technologies described herein unless an explicit indication to the contrary is made herein. In particular, use of the singular articles such as “a,” “the,” “said,” etc. should be read to recite one or more of the indicated elements unless a claim recites an explicit limitation to the contrary.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

What is claimed is:

1. An oscillator circuit comprising:
a first inverter that is electrically connected to a supply voltage, a first node, and a second node;
a second inverter that is electrically connected to the supply voltage, the second node, and a third node;
a third inverter that is electrically connected to the supply voltage, the third node, and a fourth node;
a resistor that is electrically connected to the fourth node;
an enable transistor that is electrically connected to the supply voltage and a fifth node, wherein a gate of the enable transistor is configured to receive a second enable signal;
a first capacitor that is electrically connected to the third node and a sixth node that is electrically connected to the fifth node; and
a second capacitor that is electrically connected to the sixth node and a ground,
wherein the first capacitor and the second capacitor form a capacitor divider, and
wherein the capacitor divider limits a first voltage at the first node to a voltage range between the supply voltage and the ground.

2. The oscillator circuit of claim 1, further comprising:
an enable delay switch that is electrically connected to the resistor and the fifth node, wherein a gate of the enable delay switch is configured to receive a first enable signal; and
an inverter delay string electrically connected to the gate of the enable delay switch, the inverter delay string configured to generate the second enable signal by delaying the first enable signal,
wherein the enable delay switch and the capacitor divider limits the first voltage at the first node to the voltage range between the supply voltage and the ground.

3. The oscillator circuit of claim 1, further comprising:
an inverter string electrically connected to the fourth node.

4. The oscillator circuit of claim 1, wherein the first capacitor has a first capacitance, wherein the second capacitor has a second capacitance that is equal to the first capacitance.

5. The oscillator circuit of claim 1, wherein the first inverter, the second inverter, and the third inverter are each a complementary metal-oxide-semiconductor (CMOS) inverter.

6. The oscillator circuit of claim 1, wherein the enable transistor is a P-channel metal-oxide-semiconductor (PMOS) transistor.

7. The oscillator circuit of claim 1, wherein, when the enable transistor is in an OPEN state, the first voltage at the first node is equal to the supply voltage, a second voltage at the second node is equal to the ground, a third voltage at the third node is equal to the supply voltage, and wherein a fourth voltage at the fourth node is equal to the ground.

8. The oscillator circuit of claim 7, wherein, when the enable transistor changes from the OPEN state to a CLOSED state, the first voltage at the first node changes from the supply voltage to be equal to the ground, the second voltage at the second node changes from the ground to be equal to the supply voltage, the third voltage at the third node changes from the supply voltage to be equal to the ground, and wherein the fourth voltage at the fourth node changes from the ground to be equal to the supply voltage.

9. The oscillator circuit of claim 1, wherein the first inverter, the second inverter, and the third inverter each include a plurality of transistors, and wherein all of the transistors in the first inverter, the second inverter, and the third inverter have the same oxide thickness.

10. An electronic device comprising:
an oscillator circuit including
a first inverter that is electrically connected to a supply voltage, a first node, and a second node;
a second inverter that is electrically connected to the supply voltage, the second node, and a third node;
a third inverter that is electrically connected to the supply voltage, the third node, and a fourth node;
a resistor that is electrically connected to the fourth node;
an enable transistor that is electrically connected to the supply voltage and a fifth node, wherein a gate of the enable transistor is configured to receive a second enable signal;
a first capacitor that is electrically connected to the third node and a sixth node that is electrically connected to the fifth node; and
a second capacitor that is electrically connected to the sixth node and a ground,
wherein the first capacitor and the second capacitor form a capacitor divider, and
wherein the capacitor divider limits a first voltage at the first node to a voltage range between the supply voltage and the ground.

11. The electronic device of claim 10, further comprising:
an enable delay switch that is electrically connected to the resistor and the fifth node, wherein a gate of the enable delay switch is configured to receive a first enable signal; and
an inverter delay string electrically connected to the gate of the enable delay switch, the inverter delay string configured to generate the second enable signal by delaying the first enable signal,
wherein the enable delay switch and the capacitor divider limits the first voltage at the first node to the voltage range between the supply voltage and the ground.

12. The electronic device of claim 10, further comprising:
an inverter string electrically connected to the fourth node.

13. The electronic device of claim 10, wherein the first capacitor has a first capacitance, wherein the second capacitor has a second capacitance that is equal to the first capacitance.

14. The electronic device of claim 10, wherein the first inverter, the second inverter, and the third inverter are each a complementary metal-oxide-semiconductor (CMOS) inverter.

15. The electronic device of claim 10, wherein the enable transistor is a P-channel metal-oxide-semiconductor (PMOS) transistor.

16. The electronic device of claim 10, wherein, when the enable transistor is in an OPEN state, the first voltage at the first node is equal to the supply voltage, a second voltage at the second node is equal to the ground, a third voltage at the third node is equal to the supply voltage, and wherein a fourth voltage at the fourth node is equal to the ground.

17. The electronic device of claim 16, wherein, when the enable transistor changes from the OPEN state to a CLOSED state, the first voltage at the first node changes from the supply voltage to be equal to the ground, the second voltage at the second node changes from the ground to be equal to the supply voltage, the third voltage at the third node changes from the supply voltage to be equal to the ground, and wherein the fourth voltage at the fourth node changes from the ground to be equal to the supply voltage.

18. The electronic device of claim 10, wherein the first inverter, the second inverter, and the third inverter each include a plurality of transistors, and wherein all of the transistors in the first inverter, the second inverter, and the third inverter have the same oxide thickness.

19. A method for operating an oscillator circuit, the method comprising:
generating, with a control circuitry, a first enable signal; and
outputting, with the control circuitry, the first enable to control an enable transistor of an oscillator circuit to change from an OPEN state to a CLOSED state or from the CLOSED state to the OPEN state,
wherein the oscillator circuit includes the enable transistor, a plurality of inverters, a first capacitor and a second capacitor forming a capacitor divider, and a resistor,
wherein a first inverter of the plurality of inverters is electrically connected to a supply voltage, a first node, and a second node, and
wherein the enable delay switch and the capacitor divider limits a first voltage at the first node to a voltage range between the supply voltage and the ground.

20. The method of claim 19, further comprising:
generating a second enable signal; and
outputting the second enable signal to control an enable delay switch of the oscillator circuit to change from an OPEN state to a CLOSED state or from the CLOSED state to the OPEN state, wherein the second enable signal is based on and delayed relative to the first enable signal,
wherein the oscillator circuit further includes the enable delay switch, and
wherein the enable delay switch and the capacitor divider limits the first voltage at the first node to the voltage range between the supply voltage and the ground.
